(19) United States
(12) Patent Application Publication
(10) Pub. No.: US 2004/0227223 A1
(43) Pub. Date: Nov. 18, 2004

(54) Semiconductor device, electronic device, electronic apparatus, and methods for manufacturing semiconductor device and electronic device

(76) Inventor: Toshihiro Sawamoto, Matsumoto-shi (JP)

Correspondence Address: HARNESS, DICKEY & PIERCE, P.L.C., P.O. BOX 828, BLOOMFIELD HILLS, MI, 48303, US

(21) Appl. No.: 10/801,084

(22) Filed: Mar. 15, 2004

(30) Foreign Application Priority Data
Mar. 17, 2003 (JP) 2003-072565

(51) Int. Cl. H01L 21/44; H01L 23/02

(52) U.S. Cl. 257/686; 438/109; 257/737; 438/613

(57) ABSTRACT

A technique is provided to three-dimensionally mount different types of packages with stability. According to the technique, projections are contacted to a semiconductor chip and bumps are bonded to lands disposed on a first carrier substrate so that an end of each other carrier substrate is held right above the semiconductor chip and the other carrier substrates are independently mounted above the first carrier substrate.

### RELATED APPLICATIONS

This application claims priority to Japanese Patent Application No. 2003-072565 filed Mar. 17, 2003 which is hereby expressly incorporated by reference herein in its entirety.

### BACKGROUND OF THE INVENTION

1. Technical Field of the Invention

The present invention relates to a semiconductor device, an electronic device, an electronic apparatus, and methods for manufacturing a semiconductor device and an electronic device. In particular, the present invention is suitable for application to a composite structure, such as a semiconductor package.

2. Description of the Related Art

In conventional semiconductor devices, three-dimensionally mounting semiconductor chips with carrier substrates of the same type is used to save space for mounting the semiconductor chips.

In a method for three-dimensionally mounting semiconductor chips with carrier substrates of the same type, however, stacking different types of packages and chips is difficult. If different types of packages are simply stacked, the mounting condition of the different packages is unstable because of irregular sizes of the packages.

An object of the present invention is to provide a semiconductor device, an electronic device, an electronic apparatus, and methods for manufacturing a semiconductor device and an electronic device that are capable of three-dimensionally mounting different types of packages with stability.

### SUMMARY

To solve the above mentioned problem, a semiconductor device according to an aspect of the present invention has a first semiconductor package having a first semiconductor chip; a second semiconductor package supported on the first semiconductor package so that an end of the second semiconductor package is arranged directly above the first semiconductor chip; and a first projection supporting the end of the second semiconductor package right above the first semiconductor chip.

Therefore, in this semiconductor device, the second semiconductor package is disposed on the first semiconductor package having the first semiconductor chip even when the first semiconductor package is different in size from the second semiconductor package. In addition, the second semiconductor package is supported on or above the first semiconductor chip with stability even when the end of the second semiconductor package is arranged right above the first semiconductor chip. Thus, different types of semiconductor packages are three-dimensionally mounted with stability, while increasing the flexibility in the positions where the different types of semiconductor packages are arranged. As a result, improved space-saving effectiveness is achieved.

According to an aspect of the present invention, the semiconductor device may further include a third semiconductor package supported on the first semiconductor package so that an end of the third semiconductor package is arranged directly above the first semiconductor chip; and a second projection supporting the end of the third semiconductor package directly above the first semiconductor chip.

Therefore, in this semiconductor device, the second and the third semiconductor packages are arranged on or above the first semiconductor chip, while stability of the second and the third semiconductor packages is maintained. The plurality of semiconductor packages is arranged on or above the same first semiconductor chip with stability, contributing to a reduced footprint.

According to the semiconductor device of an aspect of the present invention, the second semiconductor package may be separated (spaced apart) from the third semiconductor package.

Therefore, in this semiconductor device, heat generated by the first semiconductor chip is dissipated from the space between the second and the third semiconductor packages, while stability of the second and the third semiconductor packages is maintained, even when the second and the third semiconductor packages are arranged on or above the first semiconductor package. Thus, the plurality of semiconductor packages is arranged on or above the same first semiconductor chip without decreasing the reliability of the first semiconductor chip, resulting in a reduced footprint and suppressed malfunctions.

According to the semiconductor device of an aspect of the present invention, the second semiconductor package and the third semiconductor package may be different in at least one of size, thickness, and material.

Therefore, in this semiconductor device, the plurality of different types of semiconductor packages is arranged on or above the same semiconductor chip with stability and a reduced footprint is achieved. In addition, warping occurring in the semiconductor packages is accommodated and the connection reliability between the packages is improved.

According to the semiconductor device of an aspect of the present invention, at least one of a space between the second semiconductor package and the third semiconductor package, a space between the first semiconductor package and the second semiconductor package, and a space between the first semiconductor package and the third semiconductor package may be filled with resin.

Therefore, in this semiconductor device, resin filled in the spaces between the semiconductor packages relieves the stress occurring in the semiconductor packages. The impact resistance increases and thus the reliability of the semiconductor packages is secured, even when the plurality of semiconductor packages is independently stacked.

According to the semiconductor device of an aspect of the present invention, the first semiconductor package may include a first carrier substrate which the first semiconductor chip is flip-chip mounted on or above; and the second semiconductor package may include second semiconductor chips, a second carrier substrate which the second semiconductor chips are mounted on or above, a bump that is bonded to the first carrier substrate and that holds the second carrier substrate on or above the first semiconductor chip, and a seal for sealing the second semiconductor chips.

Therefore, in this semiconductor device, the bump is bonded to the first carrier substrate so that different types of packages are independently stacked without increasing the height, resulting in a reduced footprint.

According to the semiconductor device of an aspect of the present invention, the first semiconductor package may be a ball grid array package in which the first semiconductor chip is flip-chip mounted on or above the first carrier substrate; and the second semiconductor package is a ball grid array package or a chip-size package in which the second semiconductor chips mounted on or above the second carrier substrate are sealed by molding.

Therefore, in this semiconductor device, different types of packages are independently stacked, even when the packages are general purpose packages. Thus, a reduced footprint is achieved without decreasing the manufacturing efficiency.

According to the semiconductor device of an aspect of the present invention, the bump may be arranged on the second carrier substrate away from the mounting region of the first semiconductor chip; and the projection may be arranged so that the second carrier substrate is supported at four corners.

Therefore, the carrier substrate is supported at four corners with stability even when the bump is disposed out of balance on the second carrier substrate. The plurality of carrier substrates is arranged on or above the same semiconductor chip with stability.

According to the semiconductor device of an aspect of the present invention, the first semiconductor chip may be a logical operation element; and the second semiconductor chips may be memory elements.

Therefore, in this semiconductor device, various functions are achieved without increasing the footprint and a composite structure of memory elements is readily achieved. Thus, the storage capacity is easily increased.

According to the semiconductor device of an aspect of the present invention, the second semiconductor chips may have a three-dimensionally mounted structure.

Therefore, in this semiconductor device, the plurality of second semiconductor chips, which are different in type or size, is stacked above the first semiconductor chip. Thus, various functions are achieved and also space savings in mounting of the semiconductor chips is achieved.

According to an aspect of the present invention, an electronic device has a first package having an electronic component; a second package supported on the first package so that an end of the second package is arranged directly above the electronic component; and a projection supporting the end of the second package directly above the electronic component.

Therefore, in this electronic device, the packages are three-dimensionally mounted even when the first package is different in type from the second package. The different types of electronic components are stacked with stability, while the flexibility in arrangement is increased. Thus, improved space-saving effectiveness is achieved.

According to an aspect of the present invention, an electronic apparatus has a first semiconductor package having a semiconductor chip; a second semiconductor package supported on the first semiconductor package so that an end of the second semiconductor chip is arranged directly above the semiconductor chip; a projection supporting the end of the second semiconductor chip directly above the semiconductor chip; and a motherboard having the second semiconductor package.

Therefore, in this electronic apparatus, different types of packages having the semiconductor chips are three-dimensionally mounted. Miniaturization of the electronic apparatus is achieved without increasing malfunctions, allowing improved functionality of the electronic apparatus.

According to an aspect of the present invention, a method for manufacturing a semiconductor device has the steps of: mounting a first semiconductor chip on or above a first carrier substrate; mounting second semiconductor chips on or above a second carrier substrate; forming a first bump on the underside of the second carrier substrate away from areas surrounding at least one vertex of the second carrier substrate; forming a first projection on areas surrounding the other vertices on which the first bump is not arranged; and bonding the first bump to the first carrier substrate so that the first projection is arranged on the first semiconductor chip.

Therefore, in this method, the second carrier substrate is supported on or above the first semiconductor chip with stability even when the end of the second carrier substrate is arranged right above the first semiconductor chip. The first bump is bonded to the first carrier substrate so that the second carrier substrate is disposed above the first carrier substrate. Thus, the space-saving effectiveness is improved without complicating the manufacturing process.

According to an aspect of the present invention, the method for manufacturing a semiconductor device may further include the steps of mounting third semiconductor chips on or above a third carrier substrate; forming a second bump on the underside of the third carrier substrate away from areas surrounding at least one vertex of the third carrier substrate; forming a second projection on areas surrounding the other vertices on which the second bump is not arranged; and bonding the second bump to the first carrier substrate so that the second projection is arranged on the first semiconductor chip.

Therefore, in this method, the plurality of carrier substrates is held on or above the same semiconductor chip with stability even when the end of each of the carrier substrates is arranged right above the semiconductor chip. Thus, the footprint is further reduced without complicating the manufacturing process.

According to an aspect of the present invention, a method for manufacturing a semiconductor device has the steps of: mounting a first electronic component on or above a first carrier substrate; mounting second electronic components on or above a second carrier substrate; forming a first bump on the underside of the second carrier substrate away from areas surrounding at least one vertex of the second carrier substrate; forming a first projection on areas surrounding the other vertices on which the first bump is not arranged; and bonding the first bump to the first carrier substrate so that the first projection is arranged on the first electronic component.

Therefore, in this method, the second electronic component is arranged above the first electronic component with stability even when the end of the second carrier substrate is arranged right above the first electronic component. Thus, the footprint is reduced without complicating the manufacturing process.

### BRIEF DESCRIPTION OF THE DRAWINGS

FIG. 1 is a cross-sectional view illustrating a semiconductor device according to a first embodiment of the present invention.

FIG. 2 is a plan view illustrating the structure of a semiconductor device according to a second embodiment of the present invention.

FIGS. 3A-D are cross-sectional views illustrating a method for manufacturing a semiconductor device according to a third embodiment of the present invention.

### DETAILED DESCRIPTION

A semiconductor device, an electronic device, and methods for manufacturing the same according to the present invention will be described below with reference to the drawings.

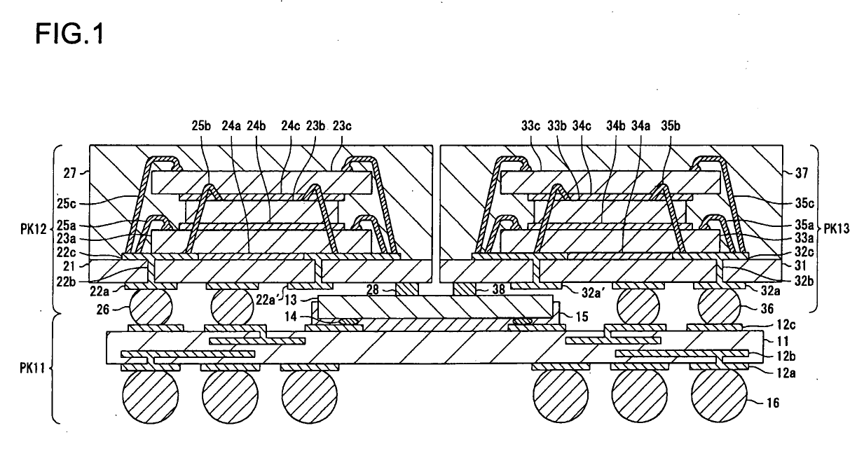

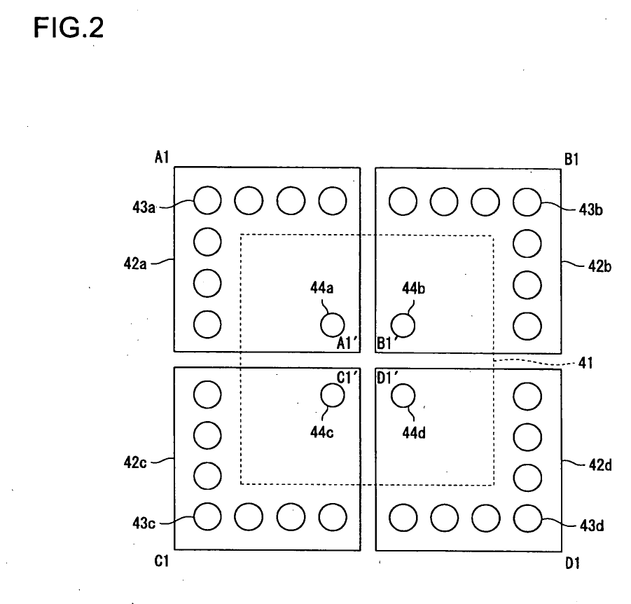

FIG. 1 shows a cross-sectional view illustrating a semiconductor device according to a first embodiment of the present invention. FIG. 2 is a plan view illustrating a schematic structure of a semiconductor device according to a second embodiment of the present invention. In this embodiment, semiconductor packages PK12 and PK13 are disposed on a semiconductor package PK11 in which a semiconductor chip (semiconductor die) 13 is mounted by anisotropic conductive film (ACF) bonding. The semiconductor package PK12 has stacked semiconductor chips (semiconductor dice) 23a to 23c that are connected by wire bonding. Similarly, the semiconductor package PK13 has stacked semiconductor chips (semiconductor dice) 33a to 33c that are connected by wire bonding.

Referring to FIG. 1, the semiconductor package PK11 has a carrier substrate 11. Lands 12a and 12c are disposed on both sides of the carrier substrate 11 and an inner wiring line 12b is disposed within the carrier substrate 11. The semiconductor chip 13 is flip-chip mounted on or above the carrier substrate 11 and a bump 14 is disposed on the semiconductor chip 13 for the flip-chip mounting. The bump 14 disposed on the semiconductor chip 13 is connected to one of the lands 12c by ACF bonding with an anisotropic conductive sheet 15. Bumps 16 used for mounting the carrier substrate 11 on or above a motherboard are disposed on the lands 12a, which are disposed on the underside of the carrier substrate 11.

Mounting the semiconductor chip 13 on or above the carrier substrate 11 by ACF bonding results in space savings in three-dimensional mounting because a space for wire-bonding or for sealing by molding is not required. Additionally, warping of the carrier substrate 11 during use is reduced because bonding of the semiconductor chip 13 to the carrier substrate 11 is achieved at lower temperatures.

The semiconductor packages PK12 and PK13 have carrier substrates 21 and 31, respectively. Lands 22a and 22a′, and lands 32a and 32a′ are disposed on the undersides of the carrier substrates 21 and 31, respectively. Lands 22c and 32c are disposed on the front sides of the carrier substrates 21 and 31, respectively. Inner wiring lines 22b and 32b are disposed within the carrier substrates 21 and 31, respectively.

Bumps 26 and 36 are arranged on the lands 22a and 32a, respectively. On the lands 22a′ and 32a′, the bumps 26 and 36 may not be arranged. The lands 22a′ and 32a′, which the bumps 26 and 36 are not arranged on, are disposed on the carrier substrates 21 and 31, respectively, so that the positions of the bumps can be adjusted. Therefore, if the type or size of the semiconductor chip 13 to be mounted on or above the carrier substrate 11 is changed, the bumps 26 and 36 are rearranged without changing the structures of the carrier substrates 21 and 31. Thus, general-purpose substrates can be used as the carrier substrates 21 and 31.

Semiconductor chips 23a and 33a are face-up mounted on or above the carrier substrates 21 and 31 with adhesive layers 24a and 34a, respectively, and are connected to the lands 22c and 32c by wire bonding with conductive wire lines 25a and 35a, respectively. Semiconductor chips 23b and 33b are face-up mounted on or above the semiconductor chips 23a and 33a away from the conductive wire lines 25a and 35a. The semiconductor chips 23b and 33b are fixed on or above the semiconductor chips 23a and 33a with adhesive layers 24b and 34b, respectively, and are connected to the lands 22c and 32c by wire bonding with conductive wire lines 25b and 35b, respectively. Semiconductor chips 23c and 33c are face-up mounted on or above the semiconductor chips 23b and 33b away from the conductive wire lines 25b and 35b. The semiconductor chips 23c and 33c are fixed on or above the semiconductor chips 23b and 33b with adhesive layers 24c and 34c, respectively, and are connected to the lands 22c and 32c by wire bonding with conductive wire lines 25c and 35c, respectively.

The bumps 26 and 36 are disposed on the lands 22a and 32a, which are disposed on the undersides of the carrier substrates 21 and 31, for mounting the carrier substrates 21 and 31 so as to hold the carrier substrates 31 and 41 on or above the semiconductor chip 13. Preferably, the bumps 26 and 36 may be supplied to the carrier substrates 21 and 31 away from a region where the semiconductor chip 13 is arranged. The bumps 36 and 46 may be arranged, for example, to have L-shaped forms along two sides of each of the carrier substrates 21 and 31.

Projections 28 and 38 are disposed on the undersides of the carrier substrates 21 and 31, respectively, to hold an end of each of the carrier substrates 21 and 31 right above the semiconductor chip 13. Therefore, the carrier substrates 21 and 31 are held on or above the carrier substrate 11 with stability even when the carrier substrates 21 and 31 are disposed above the carrier substrate 11 so as to hold an end of each of the carrier substrates 21 and 31 right above the semiconductor chip 13. Thus, the different types of semiconductor packages PK11 to PK13 are three-dimensionally mounted with stability, while increasing the flexibility in arrangement of the carrier substrates 21 and 31.

The projections 28 and 38 contact the semiconductor chip 13, and the bumps 26 and 36 are bonded to the lands 12c disposed on the carrier substrate 11 so that the carrier substrates 21 and 31 are mounted above the carrier substrate 11 so as to hold an end of each of carrier substrates 21 and 31 right above the semiconductor chip 13. Therefore, the semiconductor packages PK12 and PK13, i.e., a plurality of semiconductor packages, are mounted on or above the same semiconductor chip 13 with stability. Thus, the different types of semiconductor chips 13, 23a to 23c, and 33a to 33c are three-dimensionally mounted without increasing the footprint.

The semiconductor chip 13 may be, for example, a logical operation element, such as a CPU. The semiconductor chips 23a to 23c and 33a to 33c may be, for example, a memory element, such as a DRAM, a SRAM, an EEPROM, or a flash memory.

Therefore, various functions can be achieved without increasing the footprint, and a composite structure of memory elements can be readily achieved. Thus, the storage capacity can be easily increased.

The carrier substrates 21 and 31 may closely contact each other at their side walls or may be arranged away from each other at their side walls when the carrier substrates 21 and 31 are mounted above the carrier substrate 11. If the side wall of the carrier substrate 21 closely contacts that of the carrier substrate 31, the mounting density of the semiconductor packages PK12 and PK13 to be mounted on or above the semiconductor package PK11 increases, resulting in space savings. On the other hand, if the side wall of the carrier substrate 21 does not contact that of the carrier substrate 31, heat generated by the semiconductor chip 13 is dissipated from the space between the semiconductor packages PK12 and PK13, resulting in improved dissipation of heat generated by the semiconductor chip 13.

The sides of the carrier substrates 21 and 31 which the semiconductor chips 23a to 23c and 33a to 33c are mounted on or above are entirely sealed with sealing resin 27 and 37, respectively, for sealing the semiconductor chips 23a to 23c and 33a to 33c. Molding using a thermosetting resin, such as an epoxy resin, may be employed for sealing the semiconductor chips 23a to 23c and 33a to 33c with the sealing resin 27 and 37.

The carrier substrates 11, 21, and 31 may be, for example, a double-sided substrate, a substrate having multi-level interconnections, a build-up substrate, a tape substrate, or a film substrate. The material of carrier substrates 11, 21, and 31 may be, for example, a polyimide resin, a glass epoxy resin, a bismaleimide-triazin (BT) resin, an aramid-epoxy composite, or ceramic. The bumps 16, 26, and 36 may be, for example, a gold bump, a copper bump covered with a soldering agent, a nickel bump covered with a soldering agent, or a solder ball. The conductive wire lines 25a to 25c and 35a to 35c may comprise, for example, a gold wire or an aluminum wire. The projections 28 and 38 may be a bump, such as a solder ball, or a buffering component, such as a resin. In the above-described embodiment, one method for mounting the bumps 26 and 36 on the lands 22a and 32a of the carrier substrates 21 and 31 to mount the carrier substrates 21 and 31 above the carrier substrate 11 is illustrated, but the bumps 26 and 36 may be mounted on the lands 12c of the carrier substrate 11.

In the above-described embodiment, one method for mounting the semiconductor chip 13 on or above the carrier substrate 11 by ACF bonding is illustrated, but other adhesive bonding, such as nonconductive film (NCF) bonding, anisotropic conductive paste (ACP) bonding, or nonconductive paste film (NCP) bonding, or metallic bonding, such as solder bonding or alloy bonding, may be employed. Also, connection by wire bonding is illustrated for mounting the semiconductor chips 23a to 23c and 33a to 33c on or above the carrier substrates 21 and 31, respectively, but the semiconductor chips 23a to 23c and 33a to 33c may be flip-chip mounted on or above the carrier substrates 21 and 31. In addition, only the semiconductor chip 13 mounted on or above the carrier substrate 11 is illustrated in the above-described embodiment, but a plurality of semiconductor chips may be mounted above the carrier substrate 11.

Spaces between the semiconductor packages PK11, PK12, and PK13 may be filled with resin. Therefore, the impact resistance of the semiconductor packages PK11, PK12, and PK13 increases. Thus, the bumps 26 and 36 do not crack even when residual stress concentrates on base portions of the bumps 26 and 36, resulting in improved reliability of the semiconductor packages PK11, PK12, and PK13.

FIG. 2 is a plan view illustrating a method for arranging bumps according to the second embodiment of the present invention. In this embodiment, carrier substrates 42a to 42d are arranged above a semiconductor chip 41, each carrier substrate forming an arrangement consisting of four parts, and an end of each of the carrier substrates 42a to 42d is held right above (e.g., directly above) the semiconductor chip 41 with projections 44a to 44d.

Referring to FIG. 2, bumps 43a to 43d are disposed on the carrier substrates 42a to 42d to have L-shaped forms along two consecutive sides whose points of intersection are vertices A1 to D1 of the carrier substrates 42a to 42d, respectively. No bumps are disposed along the other two consecutive lines whose points of intersection are vertices A1′ to D1′, which are opposite to the vertices A1 to D1, of the carrier substrates 42a to 42d. The projections 44a to 44d are disposed around the vertices A1′ to D1′ of the carrier substrates 42a to 42d to support an end of each of the carrier substrates 42a to 42d right above the semiconductor chip 41.

The bumps 43a to 43d are bonded to a lower substrate which the semiconductor chip 41 is mounted on or above so that the projections 44a to 44d disposed on the carrier substrates 42a to 42d contact the surface of the semiconductor chip 41. Therefore, the carrier substrates 42a to 42d are supported with stability even when the bumps 43a to 43d are scattered unevenly on the carrier substrates 21 and 31. Therefore, the carrier substrates 42a to 42d, i.e., a plurality of carrier substrates, are arranged on or above the same semiconductor chip 41 with stability.

In above-described embodiment, a method for arranging the carrier substrates 42a to 42d above the carrier substrate 41 so that each carrier substrate forms an arrangement consisting of four parts is illustrated, but such an arrangement may consist of two, three, or over four parts. Also, a method for arranging the bumps 43a to 43d along lines of the carrier substrates 42a to 42d so as to have L-shaped forms is illustrated in the above-described embodiment, but the arrangement may be of other forms than the L-shaped forms.

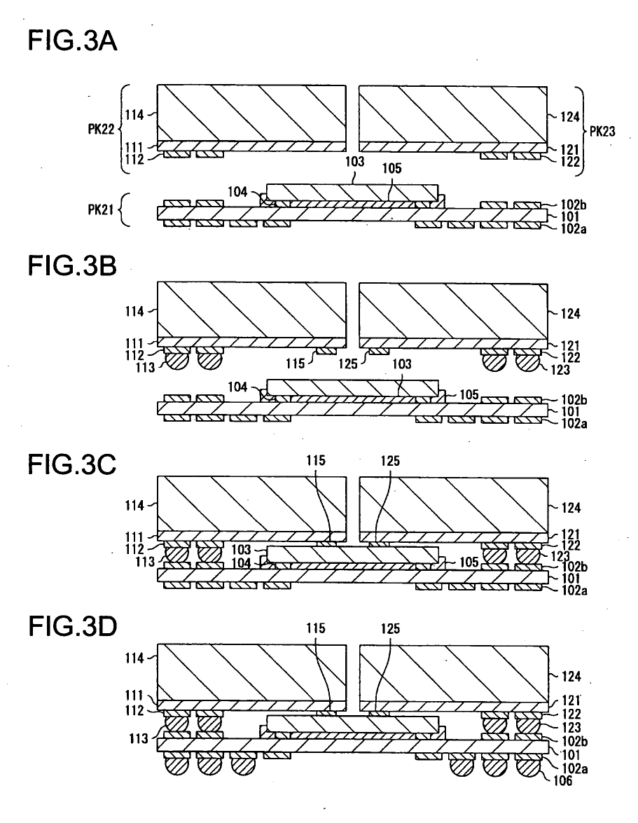

FIG. 3 is a cross-sectional view illustrating a method for manufacturing a semiconductor device according to a third embodiment of the present invention. In this embodiment, semiconductor packages PK22 and PK23 are mounted on a semiconductor package PK21 with projections 115 and 125 so as to hold an end of each of the semiconductor packages PK22 and PK23 right above a semiconductor chip 103.

Referring to FIG. 3(a), the semiconductor package PK21 has a carrier substrate 101, and lands 102a and 102b are formed on both sides of the carrier substrate 101. The semiconductor chip 103 is flip-chip mounted on or above the carrier substrate 101, and a bump 104 is disposed on the semiconductor chip 103 for the flip-chip mounting. The bump 104 disposed on the semiconductor chip 103 is bonded to one of lands 102b by ACF bonding with an anisotropic conductive sheet 105.

On the other hand, the semiconductor packages PK22 and PK23 have carrier substrates 111 and 121, respectively. Lands 112 and 122 are formed on the undersides of the carrier substrates 111 and 121, respectively. Semiconductor chips are mounted on or above the carrier substrates 111 and 121, respectively. The sides of carrier substrates 111 and 121, where the semiconductor chips are mounted, are entirely sealed with sealing resin 114 and 124, respectively. The semiconductor chips that are connected by wire bonding may be mounted on or above the carrier substrates 111 and 121. The semiconductor chips may be flip-chip mounted. The semiconductor chips may have a composite structure.

Then, as shown in FIG. 3(b), bumps 113 and 123, such as solder balls, are formed on the lands 112 and 122, respectively, away from the mounting region of the semiconductor chip 103. The projections 115 and 125 are formed on the lands 112 and 122 at positions where an end of each of the carrier substrates 111 and 121 are supported right above the semiconductor chip 103.

Then, as shown in FIG. 3(c), the semiconductor packages PK22 and PK23 are mounted on the semiconductor package PK21 so that the end of each of the carrier substrates 111 and 121 is supported with the projections 115 and 125. The bumps 113 and 123 are bonded to the lands 102b by performing solder reflow.

Then, as shown in FIG. 3(d), the bump 106 for mounting the carrier substrate 101 on or above a motherboard is formed on the land 102a disposed on the underside of the carrier substrate 101.

The above-described semiconductor device and electronic device are applicable to electronic apparatuses, such as liquid crystal displays, cellular phones, personal digital assistants, video cameras, digital cameras, or mini disc (MD) players, allowing improved functionality of electronic apparatuses and miniaturization and improvement in reliability of the electronic apparatuses.

Although the above-described embodiments are illustrated with a method for mounting semiconductor chips or semiconductor packages, the present invention is not restricted to such a method. In the present invention, ceramic devices, such as surface-acoustic-wave (SAW) devices, optical devices, such as optical modulators or optical switches, and sensors, such as magnetic sensors or biosensors, may be mounted.

What is claimed is:

1. A semiconductor device comprising:
a first semiconductor package having a first semiconductor chip;
a second semiconductor package supported on the first semiconductor package so that an end of the second semiconductor package is arranged directly above the first semiconductor chip; and
a first projection supporting the end of the second semiconductor package directly above the first semiconductor chip.

2. The semiconductor device according to claim 1, further comprising:
a third semiconductor package supported on the first semiconductor package so that an end of the third semiconductor package is arranged directly above the first semiconductor chip; and
a second projection supporting the end of the third semiconductor package directly above the first semiconductor chip.

3. The semiconductor device according to claim 2, wherein the second semiconductor package is spaced apart from the third semiconductor package.

4. The semiconductor device according to claim 2, wherein the second semiconductor package and the third semiconductor package are different in at least one of size, thickness, and material.

5. The semiconductor device according to claim 2, wherein at least one of a space between the second semiconductor package and the third semiconductor package, a space between the first semiconductor package and the second semiconductor package, and a space between the first semiconductor package and the third semiconductor package is filled with resin.

6. The semiconductor device according to claim 1, wherein the first semiconductor package has a first carrier substrate, the first semiconductor chip being flip-chip mounted on or above the first carrier substrate; and
the second semiconductor package has second semiconductor chips mounted on or above a second carrier substrate, a bump that is bonded to the first carrier substrate and that holds the second carrier substrate on or above the first semiconductor chip, and a seal for sealing the second semiconductor chips.

7. The semiconductor device according to claim 6, wherein the first semiconductor package comprises a ball grid array package in which the first semiconductor chip is flip-chip mounted on or above the first carrier substrate; and the second semiconductor package comprises at least one of a ball grid array package and a chip-size package in which the second semiconductor chips mounted on or above the second carrier substrate are sealed by molding.

8. The semiconductor device according to claim 6, wherein the bump is arranged on the second carrier substrate away from the mounting region of the first semiconductor chip; and
the projection is arranged so that the second carrier substrate is supported at four corners.

9. The semiconductor device according to claim 6, wherein the first semiconductor chip comprises a logical operation element; and
the second semiconductor chips comprise memory elements.

10. The semiconductor device according to claim 6, wherein the second semiconductor chips have a three-dimensionally mounted structure.

11. An electronic device comprising:
a first package having an electronic component;
a second package supported on the first package so that an end of the second package is arranged directly above the electronic component; and
a projection supporting the end of the second package directly above the electronic component.

12. An electronic apparatus comprising:
a first semiconductor package having a semiconductor chip;
a second semiconductor package supported on the first semiconductor package so that an end of the second semiconductor package is arranged directly above the semiconductor chip;
a projection supporting the end of the second semiconductor package directly above the semiconductor chip; and
a motherboard having the second semiconductor package.

13. A method for manufacturing a semiconductor device comprising the steps of:
mounting a first semiconductor chip on or above a first carrier substrate;
mounting second semiconductor chips on or above a second carrier substrate;
forming a first bump on the underside of the second carrier substrate away from areas surrounding at least one vertex of the second carrier substrate;
forming a first projection on areas surrounding the other vertices displaced from the first bump; and
bonding the first bump to the first carrier substrate so that the first projection is arranged on the first semiconductor chip.

14. The method for manufacturing a semiconductor device according to claim 13, further comprising the steps of:
mounting third semiconductor chips on or above a third carrier substrate;
forming a second bump on the underside of the third carrier substrate away from areas surrounding at least one vertex of the third carrier substrate;
forming a second projection on areas surrounding the other vertices displaced from the second bump; and
bonding the second bump to the first carrier substrate so that the second projection is arranged on the first semiconductor chip.

15. A method for manufacturing an electronic device comprising the steps of:
mounting a first electronic component on or above a first carrier substrate;
mounting second electronic components on or above a second carrier substrate;
forming a first bump on the underside of the second carrier substrate away from areas surrounding at least one vertex of the second carrier substrate;
forming a first projection on areas surrounding the other vertices displaced from the first bump; and
bonding the first bump to the first carrier substrate so that the first projection is arranged on the first electronic component.
